(19) United States
(12) Patent Application Publication
(10) Pub. No.: US 2006/0051925 A1
(43) Pub. Date: Mar. 9, 2006

(54) Atomic layer deposition of metal oxynitride layers as gate dielectrics

(76) Inventors: Kie Y. Ahn, Chappaqua, NY (US); Leonard Forbes, Corvallis, OR (US)

Correspondence Address: TRASK BRITT, P.O. BOX 2550, SALT LAKE CITY, UT, 84110, US

(21) Appl. No.: 11/253,542

(22) Filed: Oct. 19, 2005

Related U.S. Application Data
(63) Continuation of application No. 10/352,507, filed on Jan. 27, 2003.

(51) Int. Cl. H01L 21/336; H01L 21/31; H01L 21/3205; H01L 21/8242

(52) U.S. Cl. 438/287; 438/785; 438/761; 438/591; 438/240

(57) ABSTRACT

A metal oxynitride layer formed by atomic layer deposition of a plurality of reacted monolayers, the monolayers comprising at least one each of a metal, an oxide and a nitride. The metal oxynitride layer is formed from zirconium oxynitride, hafnium oxynitride, tantalum oxynitride, or mixtures thereof. The metal oxynitride layer is used in gate dielectrics as a replacement material for silicon dioxide. A semiconductor device structure having a gate dielectric formed from a metal oxynitride layer is also disclosed.

### CROSS-REFERENCE TO RELATED APPLICATION

This application is a continuation of application Ser. No. 10/352,507, filed Jan. 27, 2003, pending.

### FIELD OF THE INVENTION

The present invention relates to a semiconductor device structure and a method for forming the same and, more specifically, to a metal oxynitride gate dielectric and a method for forming the metal oxynitride gate dielectric using atomic layer deposition.

### BACKGROUND OF THE INVENTION

Silicon dioxide (“SiO₂”) has been used as a material to form gate dielectrics, which are used in many semiconductor devices such as field effect transistor (“FET”) devices. The FET is an active device used in complementary metal oxide semiconductor (“CMOS”) integrated circuit technology. As shown in FIG. 1, a conventional FET device includes a semiconductor substrate 2 having a channel 4 that is electrically connected to a source 6 and drain 8. When a voltage difference is present between the source 6 and drain 8, current flows through the channel 4. The amount of current flowing through the channel 4 is controlled by altering the voltage applied to gate 10, which is a conductive layer overlying the channel 4. The gate 10 is typically formed from polycrystalline silicon that is highly doped and annealed to increase its conductivity. The gate 10 is separated from the channel 4 by gate dielectric 12, which insulates the gate 10 from the semiconductor substrate 2. Since the gate dielectric 12 is insulating, little or no current flows between the gate 10 and channel 4. However, the gate dielectric 12 allows the gate voltage to induce an electrical field in channel 4.

Performance of semiconductor devices has increased dramatically over the past few years as a result of increased circuit density on the semiconductor substrate 2, which has resulted in a corresponding increase in the number of FETs on the semiconductor devices. As the density of the semiconductor devices increases, it is necessary to decrease the size of circuit components that form the semiconductor devices. The size of the FETs is decreased by decreasing the channel length and the channel width. Smaller channel lengths require reduced operating voltages, which result in decreased output. To compensate for the decreased output, one solution has been to reduce the thickness of the gate dielectric 12 to bring the gate 10 in closer proximity to the channel 4 to enhance the field effect.

SiO₂ is commonly used as a gate dielectric material because it has superior isolation qualities, forms a thermodynamically and electrically stable interface with silicon, and can be applied in a layer as thin as 15 Å. However, if the thickness of SiO₂ gate dielectric 12 is decreased below 15 Å, leakage currents exceed an undesirable level of 1 A/cm² at 1V. In addition, boron or other dopants penetrate through the dielectric material. Therefore, other dielectric materials, such as Ta₂O₅, SrTiO₃, Al₂O₃, ZrO₂, and HfO₂, have been investigated to replace SiO₂. An optimal replacement dielectric material has a high dielectric constant, a high permittivity and a wide band gap, and must be thermodynamically stable with silicon. Using Ta₂O₅, SrTiO₃, or Al₂O₃ is problematic because they are not thermodynamically stable with silicon (they react with silicon to form an undesirable oxide layer). Using ZrO₂ or HfO₂ is also problematic because at the temperatures necessary for their deposition, the semiconductor substrate 2 oxidizes and forms an oxide layer at an interface between the semiconductor substrate 2 and the gate dielectric 12. This oxide layer increases the effective thickness of the metal oxide and reduces its effectiveness as a gate dielectric material. In addition, the oxide layer has a weak resistance to oxygen diffusion, causing growth of interfacial SiO₂ during high temperature annealing. In addition, ZrO₂ layers react with the polysilicon in the gate 10 and cause an increase in leakage current.

Zirconium oxynitride (“ZrON”) has also been investigated as a gate dielectric material. In Koyama et al., “Thermally Stable Ultra-Thin Nitrogen Incorporated ZrO₂ Gate Dielectric Prepared by Low Temperature Oxidation of ZrN,” Tech. Dig. IEDM, 459-462 (2001), a ZrON layer is formed by sputter depositing zirconium nitride (“ZrN”) on a substrate. The ZrN is then oxidized at 500° C. by rapid thermal oxidation to produce the ZrON layer. The resulting ZrON layer is alleged to have a capacitance equivalent thickness of 15 Å and provide reduced oxygen diffusion and boron penetration. In addition, zirconium silicide formation at the interface of polysilicon and ZrON layers is inhibited at 1000° C.

In U.S. Pat. No. 6,013,553 to Wallace et al., a semiconductor device structure having a ZrON gate dielectric layer is disclosed. The ZrON gate dielectric layer is formed by depositing zirconium on a substrate, such as by sputtering, evaporation, chemical vapor deposition (“CVD”), or plasma CVD. The zirconium is oxynitridated by exposing the zirconium to an oxygen/nitrogen atmosphere to form the ZrON gate dielectric layer. Alternatively, the zirconium is nitridated in a nitrogen atmosphere to form a ZrN layer, which is oxidized to ZrON using an oxygen anneal process.

Another technique used in semiconductor processing is atomic layer deposition (“ALD”), which is a self-limiting CVD technique that is also known as alternately pulsed CVD. ALD uses a self-limiting interaction between gaseous precursors and a surface of the semiconductor substrate to form thin, conformal layers on the semiconductor substrate. ALD was originally developed to manufacture luminescent and dielectric films used in electroluminescent displays. ALD has also been used to deposit doped zinc sulfide films, alkaline earth metal sulfide films, epitaxial 11-V and II-VI films, and nonepitaxial crystalline or amorphous oxide and nitride films.

What is desired is a gate dielectric material having a high dielectric constant and a wide band gap that is capable of being precisely deposited on a semiconductor substrate. The gate dielectric material must provide a low leakage current and a reduced boron penetration and oxygen diffusion through the gate dielectric material.

### BRIEF SUMMARY OF THE INVENTION

The present invention comprises a method of forming a metal oxynitride layer. The method comprises providing a semiconductor substrate and forming, by ALD, a layer that consists of a metal oxynitride in contact with a surface of the semiconductor substrate. The layer has a uniform composition and consists of a metal, oxygen, and nitrogen. The layer is a metal oxynitride selected from the group consisting of zirconium oxynitride, hafnium oxynitride, and mixtures thereof. A plurality of gaseous precursors may be separately introduced to the surface of the semiconductor substrate and may adsorb to the surface of the semiconductor substrate to form the metal oxynitride layer. The plurality of gaseous precursors may consist of a metal gaseous precursor, an oxygen-containing gaseous precursor, and a nitrogen-containing gaseous precursor. The metal gaseous precursor may be selected from the group consisting of zirconium tetrachloride, zirconium tetraiodide, hafnium tetrachloride, and hafnium tetraiodide.

The present invention also relates to a method of forming a semiconductor device structure. The method comprises providing a semiconductor substrate and forming, by ALD, a gate dielectric layer that consists of a metal oxynitride in contact with a surface of the semiconductor substrate. The gate dielectric layer has a uniform composition and consists of a metal, oxygen, and nitrogen. The gate dielectric layer is a metal oxynitride selected from the group consisting of zirconium oxynitride, hafnium oxynitride layer, and mixtures thereof A gate is formed over the gate dielectric layer. A plurality of gaseous precursors may be separately introduced to the surface of the semiconductor substrate. The plurality of gaseous precursors may consist of a metal gaseous precursor, an oxygen-containing gaseous precursor, and a nitrogen-containing gaseous precursor. The metal gaseous precursor may be selected from the group consisting of zirconium tetrachloride, zirconium tetraiodide, hafnium tetrachloride, and hafnium tetraiodide.

The present invention also relates to a method of forming a metal oxynitride layer that comprises providing a semiconductor substrate and reacting a plurality of monolayers to form a metal oxynitride layer that consists of a metal, oxygen, and nitrogen. The metal oxynitride layer comprises a uniform composition and is a metal oxynitride selected from the group consisting of zirconium oxynitride, hafnium oxynitride layer, and mixtures thereof

### BRIEF DESCRIPTION OF THE SEVERAL VIEWS OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 is a cross-sectional view of a field effect transistor device of the prior art;

FIG. 2 and FIG. 3 are cross-sectional views during fabrication of a semiconductor device structure according to an embodiment of the present invention; and

FIG. 4 illustrates a semiconductor device structure of the present invention.

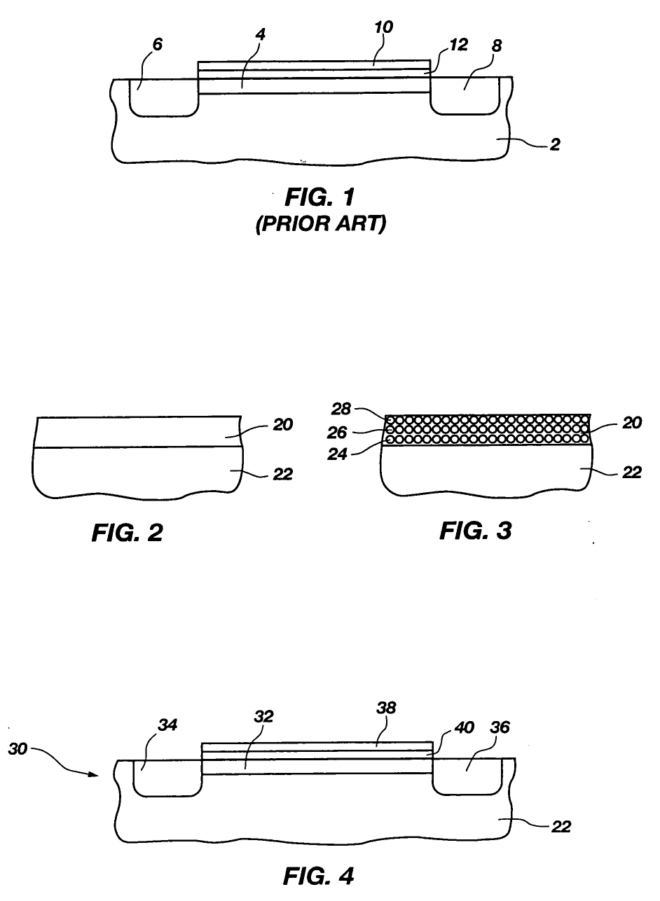

### DETAILED DESCRIPTION OF THE INVENTION

A method of forming a metal oxynitride layer by atomic layer deposition (“ALD”) is disclosed. The metal oxynitride layer is formed from zirconium oxynitride, hafnium oxynitride, tantalum oxynitride, or mixtures thereof. As used herein, the term “atomic layer deposition” refers to a deposition process that is broken up into a sequence of discrete steps, where each step is self-limiting and is executed to the self-limiting point. An ALD layer is formed by self-limiting reactions or adsorptions between a surface of a semiconductor substrate and a plurality of gaseous precursors. By using ALD, the metal oxynitride layer is enabled to be precisely deposited as a thin layer over the semiconductor substrate. A semiconductor device structure having the metal oxynitride layer formed by ALD is also disclosed. The metal oxynitride layer is used as a gate dielectric material in the semiconductor device structure.

The methods and structures described herein do not form a complete process flow for manufacturing integrated circuits. The remainder of the process flow is known to those of ordinary skill in the art. Accordingly, only the process acts and structures necessary to understand the present invention are described.

As shown in FIG. 2, the metal oxynitride layer 20 may be deposited on the semiconductor substrate 22 by ALD, which uses a self-limiting interaction between the plurality of gaseous precursors and the surface of the semiconductor substrate 22. The semiconductor substrate 22 may include a semiconductor wafer or other substrate comprising a layer of semiconductor material. The term “semiconductor substrate” as used herein includes not only silicon wafers but also silicon on insulator (“SOI”) substrates, silicon on sapphire (“SOS”) substrates, epitaxial layers of silicon on a base semiconductor foundation and other semiconductor materials such as silicon-germanium, germanium, gallium arsenide and indium phosphide.

Under favorable conditions, the plurality of gaseous precursors may adsorb to the surface of the semiconductor substrate 22 and react with one another to form the metal oxynitride layer 20. Since the reactions involved in ALD are self-limiting, precise deposition of the metal oxynitride layer 20 may be possible, which allows a thickness, uniformity, conformality, and quality of the metal oxynitride layer 20 to be controlled. ALD techniques are known in the art and have been used in semiconductor processing, as described in Sneh et al., “Thin Film Atomic Layer Deposition Equipment for Semiconductor Processing,” Thin Solid Films 402 (2002) 248-261, incorporated in its entirety by reference herein.

The plurality of gaseous precursors may be separately introduced, or pulsed, to the surface of the semiconductor substrate 22. The plurality of gaseous precursors may include at least one metal gaseous precursor and at least two nonmetallic gaseous precursors. While the examples and embodiments disclosed herein describe using three gaseous precursors, it is understood that more than three gaseous precursors may also be used. The metal gaseous precursor may be a volatile, reactive, gas precursor that includes the metal ultimately to be deposited in the metal oxynitride layer 20. The nonmetallic gaseous precursors may include an oxygen-containing gaseous precursor and a nitrogen-containing gaseous precursor. Each of the metal gaseous precursor, the oxygen-containing gaseous precursor, and the nitrogen-containing gaseous precursor may be separately introduced into an ALD reactor to deposit metal, oxide, and nitride monolayers 24, 26, and 28, respectively, on the surface of the semiconductor substrate 22, as shown in FIG. 3. As used herein, the term “monolayer” refers to a single layer comprising a single type of atom that is deposited at one time on the semiconductor substrate 22. The monolayer has a thickness that is approximately equivalent to the thickness of the relevant atom. Although FIG. 3 illustrates one of each of metal, oxide, and nitride monolayers 24, 26, and 28, it is understood that the metal oxynitride layer 20 may include a plurality of metal, oxide, and nitride monolayers 24, 26, and 28.

To form the metal oxynitride layer 20, the metal monolayer 24, approximately one atom thick, may be deposited by separately introducing the metal gaseous precursor into the ALD reactor. The metal gaseous precursor reacts with the surface of the semiconductor substrate 22 to form the metal monolayer 24. Excess metal gaseous precursor and any byproducts produced during the reaction with the surface of the semiconductor substrate 22 may be removed by purging the ALD reactor with an inert gas, such as nitrogen or argon. The inert gas may be introduced into the ALD reactor for a sufficient amount of time to purge the gaseous precursors and byproducts. After purging the metal gaseous precursor, an oxide monolayer 26 may be deposited by separately introducing the oxygen-containing nonmetallic gaseous precursor into the ALD reactor. Excess oxygen-containing nonmetallic gaseous precursor and any byproducts may be removed by purging with the inert gas. A nitride monolayer 28 may be deposited by separately introducing the nitrogen-containing gaseous nonmetallic precursor into the ALD reactor.

The order in which the gaseous precursors are introduced, or pulsed, into the ALD reactor is not critical to the operability of the invention. Therefore, it is also contemplated that the pulsing order of the gaseous precursors may include introducing the oxygen-containing or nitrogen-containing nonmetallic gaseous precursors into the ALD reactor before the metal gaseous precursor. The deposition of metal, oxide, and nitride monolayers 24, 26, and 28 may be repeated until the metal oxynitride layer 20 is a desired thickness, with each deposition cycle depositing a monolayer approximately 0.25-2 Å thick. The metal oxynitride layer 20 may be approximately 15-200 Å thick. Preferably, the metal oxynitride layer 20 is approximately 20-100 Å thick. Since the metal oxynitride layer 20 is achieved by repetitive deposition of the metal, oxide, and nitride monolayers 24, 26, and 28, the thickness of the metal oxynitride layer 20 may be simply controlled by altering the number of deposition cycles. For instance, to form a metal oxynitride layer 20 less than approximately 20 Å thick, the number of deposition cycles may simply be reduced compared to the number of deposition cycles necessary to form a metal oxynitride layer 20 at a greater thickness. Approximately 800 to 1200 deposition cycles may be used to form the metal oxynitride layer 20 of the desired thickness. The deposited metal, oxide, and nitride monolayers 24, 26, and 28 may then be reacted to form the metal oxynitride layer 20.

To form the metal, oxide and nitride monolayers 24, 26, and 28, volatile, reactive, gaseous precursors may be used. The gaseous precursors may be introduced into the ALD reactor using a precursor carrier gas, which may be the same or a different gas than the purge gas. The metal gaseous precursor may be a halogenated metal precursor, such as a halogenated zirconium, halogenated hafnium, or halogenated tantalum precursor, depending on the metal desired in the metal oxynitride layer 20. For the sake of example only, if the metal oxynitride layer 20 is a ZrON layer, the metal gaseous precursor may be zirconium tetrachloride (“ZrCl₄”) or zirconium tetraiodide (“ZrI₄”). The nonmetallic gaseous precursor may be a gaseous precursor including either hydrogen and oxygen or hydrogen and nitrogen, such as water (“H₂O”), hydrogen peroxide (“H₂O₂”), ammonia (“NH₃”), tert-butylamine (“t-BuNH₂”), allylamine (“allylNH₂”), or 1,1-dimethylhydrazine (“DMHy”). The nitrogen-containing nonmetallic gaseous precursors are reductive nitrogen sources, with t-BuNH₂ and allylNH₂ being more reductive nitrogen sources than NH₃.

ALD includes, but is not limited to, reaction sequence ALD (“RS-ALD”) and chemisorption-saturated ALD (“CS-ALD”). RS-ALD uses sequential surface chemical reactions of each of the gaseous precursors with the surface of the semiconductor substrate 22. In contrast, CS-ALD utilizes a chemisorption saturation process of one gaseous precursor to the surface of the semiconductor substrate 22, followed by an exchange reaction between the chemisorbed gaseous precursor and any additional gaseous precursors.

To allow the gaseous precursors to adsorb to the semiconductor substrate 22, the semiconductor substrate 22 may be prepared by etching in hydrofluoric acid to remove native SiO₂ that may be present. The semiconductor substrate 22 may then be placed in the ALD reactor, such as a conventional flow-type ALD reactor. ALD reactors are known in the art and include, but are not limited to, a conventional flow-type hot-wall horizontal ALD reactor or a flow-type F-120 ALD reactor available from ASM Microchemistry Ltd. (Espoo, Finland). ALD of the metal oxynitride layer 20 is described below as deposition of a ZrON layer. However, it is understood that other metal oxynitride layers including, but not limited to, hafnium oxynitride or tantalum oxynitride layers may be formed using an appropriately selected metal gaseous precursor.

ALD of the ZrON layer on the surface of the semiconductor substrate 22 may be achieved by placing a zirconium precursor, such as ZrI₄ or ZrCl₄, in an open boat in the ALD reactor. The ZrON layer may be deposited at a temperature between approximately 230° C. and approximately 500° C. The pressure in the ALD reactor may be maintained at between approximately 220 Pa and 270 Pa, such as at approximately 250 Pa. The zirconium precursor may be evaporated from the open boat and reacted with the prepared surface of the semiconductor substrate 22 to form a zirconium monolayer. To form the oxide monolayer 26, the oxygen-containing nonmetallic gaseous precursor, such as H₂O—H₂O₂ vapor, may be introduced into the ALD reactor. A reductive nitrogen source, such as t-BuNH₂ or allylNH₂, may be introduced into the ALD reactor to form the nitride monolayer 28. To improve the rate of nitride deposition, NH₃ may optionally be used with t-BuNH₂ or allylNH₂. Advantageously, the NH₃ may also reduce the incorporation of carbon and hydrogen impurities in the ZrON layer, which may result from decomposition of the t-BuNH₂ or allylNH₂. Each of the gaseous precursors may be introduced into the ALD reactor for approximately 100-500 milliseconds. While a specific pulsing order is described above, it is understood that the pulsing order of the gaseous precursors may be altered without departing from the scope of the invention.

To avoid mixing the gaseous precursors and having undesirable reactions with the surface of the semiconductor substrate 22, the ALD reactor may be purged with the purge gas between pulses of the gaseous precursors. The purge gas may be introduced into the ALD reactor for a sufficient amount of time to remove each gaseous precursor after each precursor pulse. For instance, a purge time of approximately 0.7-3 seconds may be used. Preferably, a purge time of approximately two seconds is used. Nitrogen may be used as both the purge gas and as a carrier gas for the gaseous precursor.

The deposited zirconium, oxide, and nitride monolayers 24, 26, and 28 may be reacted to form the ZrON layer, which may be used to replace SiO₂ as a gate dielectric material. The ZrON layer may have a high dielectric constant, a wide band gap, a permittivity value above approximately 20, and low levels of impurities. When used as a gate dielectric material, the ZrON layer deposited by ALD may provide a low leakage current and a reduced boron penetration and oxygen diffusion through the gate dielectric material.

Forming the metal oxynitride layer 20 by ALD provides numerous advantages over other processes, such as sputtering, CVD, and physical vapor deposition (“PVD”) processes. First, using ALD allows the metal oxynitride layer 20 to be deposited with a high degree of large area uniformity and conformality. Approximately 100% conformality, even over tough substrate topologies and robust processes, may be achieved. Second, the thickness of the metal oxynitride layer 20 may be easily controlled by adjusting the number of deposition cycles. Therefore, any changes in the thickness of the metal oxynitride layer 20 may be easily accommodated upon technology generation advance instead of requiring additional process development. In addition, each deposition cycle may be performed in less than one second in a properly designed flow-type ALD reactor so increasing the number of deposition cycles has minimal effect on semiconductor wafer throughput. Third, ALD provides continuity at any interfaces between materials in the semiconductor device structure, which prevents poorly defined nucleation regions that are typically present in layers deposited by CVD or PVD. This continuity may be achieved by preparing the surface of the semiconductor substrate 22 so that the surface reacts directly with the first gaseous precursor. Fourth, ALD may be performed at low temperatures and under mild oxidizing conditions, which is advantageous for gate dielectric processes where deposition of nonsilicon gate dielectric materials results in oxidation of the semiconductor substrate 22. Fifth, ALD may allow alloy composite layers and multilayer laminate layers to be formed due to the precision with which the individual monolayers may be deposited. Sixth, ALD provides unprecedented process robustness because ALD is free of first wafer effects and chamber dependence. Therefore, ALD process may be easily transferred from development to production and from 200 mm to 300 mm wafer size.

The metal oxynitride layer may be used as a gate dielectric material in a semiconductor device structure 30, as shown in FIG. 4. The semiconductor device structure 30 includes a semiconductor substrate 22 having a channel 32 that is electrically connected to source 34 and drain 36. The metal oxynitride layer may be deposited over the semiconductor substrate 22 to form gate dielectric 40, as previously described. After the gate dielectric 40 is formed, gate 38 is deposited by conventional techniques, such as from doped polysilicon, metal, or a conductive metal oxide.

### EXAMPLE 1

### Formation of the ZrON Layer by ALD

A semiconductor substrate 22 that has been previously etched in hydrofluoric acid to remove native SiO₂ is placed in a hot-wall horizontal flow-type ALD reactor. The pressure in the ALD reactor is maintained at approximately 250 Pa. ZrI₄ is evaporated in an open boat inside the ALD reactor, which is maintained at 240° C. The evaporated ZrI₄ is transported from one side of a reactor zone of the ALD reactor to the other side to form the zirconium monolayer on the surface of the semiconductor substrate. After purging the ZrI₄ for approximately two seconds, H₂O—H₂O₂ vapor, which is generated in an external reservoir at room temperature, is introduced into the ALD reactor through needle and solenoid valves to form the oxide monolayer. After purging the H₂O—H₂O₂ vapor for approximately two seconds, t-BuNH₂ or allylNH₂ is introduced into the ALD reactor through needle and solenoid valves to form the nitride monolayer. Optionally, NH₃ is introduced into the ALD reactor with the t-BuNH₂ or allylNH₂ to improve the rate of nitride deposition. The ZrON layer is formed by successive adsorption of the evaporated ZrI₄, the H₂O—H₂O₂, and the —BuNH₂ or allylNH₂ with the surface of the semiconductor substrate 22.

While the present invention has been described of exemplary embodiments, it is not so limited and additions, deletions and modifications to the disclosed embodiments will be apparent to those of ordinary skill in the art and made without departing from the scope of the invention as hereinafter claimed.

What is claimed is:

1. A method of forming a metal oxynitride layer, comprising:
providing a semiconductor substrate; and
forming a layer that consists of a metal oxynitride in contact with a surface of the semiconductor substrate by atomic layer deposition, wherein the layer has a uniform composition, wherein the layer consists of a metal, oxygen, and nitrogen, and wherein the layer is a metal oxynitride selected from the group consisting of zirconium oxynitride, hafnium oxynitride, and mixtures thereof.

2. The method of claim 1, wherein forming a layer that consists of a metal oxynitride in contact with a surface of the semiconductor substrate by atomic layer deposition comprises separately introducing a plurality of gaseous precursors to the surface of the semiconductor substrate, the plurality of gaseous precursors consisting of a metal gaseous precursor, an oxygen-containing precursor, and a nitrogen-containing precursor.

3. The method of claim 2, wherein separately introducing a plurality of gaseous precursors to the surface of the semiconductor substrate comprises separately introducing the metal gaseous precursor selected from the group consisting of zirconium tetrachloride, zirconium tetraiodide, hafnium tetrachloride, and hafnium tetraiodide to the surface of the semiconductor substrate.

4. The method of claim 2, wherein separately introducing a plurality of gaseous precursors to the surface of the semiconductor substrate comprises separately introducing the oxygen-containing gaseous precursor selected from the group consisting of at least one of water and hydrogen peroxide to the surface of the semiconductor substrate and separately introducing the nitrogen-containing gaseous precursor selected from the group consisting of at least one of ammonia, tert-butylamine, allylamine, and 1,1-dimethylhydrazine to the surface of the semiconductor substrate.

5. The method of claim 1, wherein forming a layer that consists of a metal oxynitride in contact with a surface of the semiconductor substrate by atomic layer deposition comprises forming monolayers of metal, oxide, and nitride and reacting the metal monolayers, the oxide monolayers, and the nitride monolayers to form the layer that consists of the metal oxynitride.

6. The method of claim 1, wherein forming a layer that consists of a metal oxynitride in contact with a surface of the semiconductor substrate by atomic layer deposition comprises forming the layer that consists of the metal oxynitride at a thickness that ranges from approximately 15 Å to approximately 200 Å.

7. The method of claim 1, wherein forming a layer that consists of a metal oxynitride in contact with a surface of the semiconductor substrate by atomic layer deposition comprises forming at least one monolayer of a metal selected from the group consisting of zirconium, hafnium, and mixtures thereof and reacting the at least one monolayer of the metal with oxide monolayers and nitride monolayers.

8. A method of forming a semiconductor device structure, comprising:
providing a semiconductor substrate;
forming a gate dielectric layer that consists of a metal oxynitride in contact with a surface of the semiconductor substrate by atomic layer deposition, wherein the gate dielectric layer has a uniform composition, wherein the gate dielectric layer consists of a metal, oxygen, and nitrogen, and wherein the gate dielectric layer is a metal oxynitride selected from the group consisting of zirconium oxynitride, hafnium oxynitride layer, and mixtures thereof; and
forming a gate over the gate dielectric layer.

9. The method of claim 8, wherein forming a gate dielectric layer that consists of a metal oxynitride in contact with a surface of the semiconductor substrate by atomic layer deposition comprises separately introducing a plurality of gaseous precursors to the surface of the semiconductor substrate, the plurality of gaseous precursors consisting of a metal gaseous precursor, an oxygen-containing precursor, and a nitrogen-containing precursor.

10. The method of claim 9, wherein separately introducing a plurality of gaseous precursors to the surface of the semiconductor substrate comprises separately introducing the metal gaseous precursor selected from the group consisting of zirconium tetrachloride, zirconium tetraiodide, hafnium tetrachloride, and hafnium tetraiodide to the surface of the semiconductor substrate.

11. The method of claim 9, wherein separately introducing a plurality of gaseous precursors to the surface of the semiconductor substrate comprises separately introducing at least one of water and hydrogen peroxide as the oxygen-containing gaseous precursor to the surface of the semiconductor substrate and separately introducing at least one of ammonia, tert-butylamine, allylamine, and 1,1-dimethylhydrazine as the nitrogen-containing gaseous precursor to the surface of the semiconductor substrate.

12. The method of claim 8, wherein forming a gate dielectric layer that consists of a metal oxynitride in contact with a surface of the semiconductor substrate by atomic layer deposition comprises forming monolayers that consist of metal monolayers, oxide monolayers, and nitride monolayers and reacting the metal monolayers, oxide monolayers, and nitride monolayers to form the gate dielectric layer.

13. The method of claim 8, wherein forming a gate dielectric layer that consists of a metal oxynitride in contact with a surface of the semiconductor substrate by atomic layer deposition comprises forming the gate dielectric layer at a thickness that ranges from approximately 15 Å to approximately 200 Å.

14. A method of forming a metal oxynitride layer, comprising:
providing a semiconductor substrate; and
reacting a plurality of monolayers to form a metal oxynitride layer that consists of a metal, oxygen, and nitrogen, wherein the metal oxynitride layer comprises a uniform composition and wherein the metal oxynitride layer is a metal oxynitride selected from the group consisting of zirconium oxynitride, hafnium oxynitride layer, and mixtures thereof.

15. The method of claim 14, wherein reacting a plurality of monolayers to form a metal oxynitride layer that consists of a metal, oxygen, and nitrogen comprises forming the metal oxynitride layer at a thickness that ranges from approximately 15 Å to approximately 200 Å.

16. The method of claim 14, wherein reacting a plurality of monolayers to form a metal oxynitride layer that consists of a metal, oxygen, and nitrogen comprises reacting at least one monolayer of a metal selected from the group consisting of zirconium, hafnium, and mixtures thereof with at least one oxide monolayer and at least one nitride monolayer.
